(19) United States
(12) Patent Application Publication
(10) Pub. No.: US 2012/0286237 A1
(43) Pub. Date: Nov. 15, 2012

(54) SEMICONDUCTOR LIGHT EMITTING DEVICE AND WAFER

(75) Inventors: Hajime Nago, Kanagawa-ken (JP); Koichi Tachibana, Kanagawa-ken (JP); Shigeya Kimura, Kanagawa-ken (JP); Takahiro Sato, Kanagawa-ken (JP); Taisuke Sato, Kanagawa-ken (JP); Toshihide Ito, Tokyo (JP); Shinya Nunoue, Chiba-ken (JP)

(73) Assignee: Kabushiki Kaisha Toshiba, Tokyo (JP)

(21) Appl. No.: 13/222,185

(22) Filed: Aug. 31, 2011

(30) Foreign Application Priority Data
May 13, 2011 (JP) 2011-107977

(51) Int. Cl. H01L 33/06

(52) U.S. Cl. 257/13; 257/E33.008

(57) ABSTRACT

According to one embodiment, a semiconductor light emitting device includes: an n-type semiconductor layer, a p-type semiconductor layer, and a light emitting part. The light emitting part is provided between the n-type semiconductor layer and the p-type semiconductor layer. The light emitting part includes: a plurality of well layers including Inₓ₁Ga₁₋ₓ₁N (0<x1<1); and a barrier layer provided between the well layers and including GaN. The well layers including a p-side well layer being nearest to the p-type semiconductor layer among the well layers. The p-side well layer is thicker than all the well layers except the p-side well layer among the well layers. An In composition ratio in the p-side well layer is lower than an In composition ratio in all the well layers except the p-side well layer. A thickness of the barrier layer is not more than twice a thickness of the p-side well layer.

### CROSS-REFERENCE TO RELATED APPLICATIONS

This application is based upon and claims the benefit of priority from the prior Japanese Patent Application No. 2011-107977, filed on May 13, 2011; the entire contents of which are incorporated herein by reference.

### FIELD

Embodiments described herein relate generally to a semiconductor light emitting device, and a wafer.

### BACKGROUND

Semiconductor light emitting devices such as light emitting diodes or laser diodes utilizing nitride semiconductors have been developed. In semiconductor light emitting devices, there is a problem that the light emission efficiency decreases as supplied current density becomes higher.

For example, in a semiconductor light emitting device having a multi quantum well structure is configured to adjust the dependence of light emission efficiency on current density by varying the thickness of a plurality of well layers. In this case, if high efficiency is obtained when the current density is high, for example, the efficiency decreases at a low current density, making it difficult to obtain a high efficiency in a wide current density range.

### BRIEF DESCRIPTION OF THE DRAWINGS

FIG. 1 is a schematic cross-sectional view showing a semiconductor light emitting device according to a first embodiment;

FIG. 2 is a schematic cross-sectional view showing a whole configuration of the semiconductor light emitting device according to the first embodiment;

FIG. 3 is a schematic cross-sectional view showing a part of the semiconductor light emitting device according to the first embodiment;

FIG. 4 is a graph showing the characteristics of the semiconductor light emitting devices;

FIG. 5 is a graph showing the characteristics of the semiconductor light emitting devices;

FIG. 6 is a graph showing the characteristics of the semiconductor light emitting devices;

FIG. 7 is a graph showing the characteristics of the semiconductor light emitting devices; and

FIG. 8 is a schematic cross-sectional view showing a wafer according to a second embodiment.

### DETAILED DESCRIPTION

In general, according to one embodiment, a semiconductor light emitting device includes: an n-type semiconductor layer, a p-type semiconductor layer, and a light emitting part. The n-type semiconductor layer includes a nitride semiconductor. The p-type semiconductor layer includes a nitride semiconductor. The light emitting part is provided between the n-type semiconductor layer and the p-type semiconductor layer. The light emitting part includes: a plurality of well layers including Inₓ₁Ga₁₋ₓ₁N (0<x1<1); and a barrier layer provided between the well layers and including GaN. The well layers including a p-side well layer being nearest to the p-type semiconductor layer among the well layers, and other well layers being all well layers except the p-side well layer among the well layers,. The p-side well layer is thicker than the other well layers. An In composition ratio in the p-side well layer is lower than an In composition ratio in the other well layers. A thickness of the barrier layer is not more than twice a thickness of the p-side well layer.

According to another embodiment, a wafer including: an n-type semiconductor layer, a p-type semiconductor layer, and a light emitting part. The n-type semiconductor layer includes a nitride semiconductor. The p-type semiconductor layer includes a nitride semiconductor. The light emitting part is provided between the n-type semiconductor layer and the p-type semiconductor layer. The light emitting part includes: a plurality of well layers including Inₓ₁Ga₁₋ₓ₁N (0<x1<1); and a barrier layer provided between the well layers and including GaN. The well layers include a p-side well layer being nearest to the p-type semiconductor layer among the well layers, and other well layers being all well layers except the p-side well layer among the well layers,. The p-side well layer is thicker than the other well layers. An In composition ratio in the p-side well layer is lower than an In composition ratio in the other well layers. A thickness of the barrier layer is not more than twice a thickness of the p-side well layer.

Exemplary embodiments of the invention will now be described in detail with reference to the drawings.

The drawings are schematic or conceptual; and the relationships between the thickness and width of portions, the proportions of sizes among portions, etc., are not necessarily the same as the actual values thereof. Further, the dimensions and proportions may be illustrated differently among the drawings, even for identical portions.

In the specification and the drawings of the application, components similar to those described in regard to a drawing thereinabove are marked with like reference numerals, and a detailed description is omitted as appropriate.

### First Embodiment

The embodiment relates to semiconductor light emitting devices such as LEDs and LDs. In the following, an LED will be described as an example of a semiconductor light emitting device according to the embodiment.

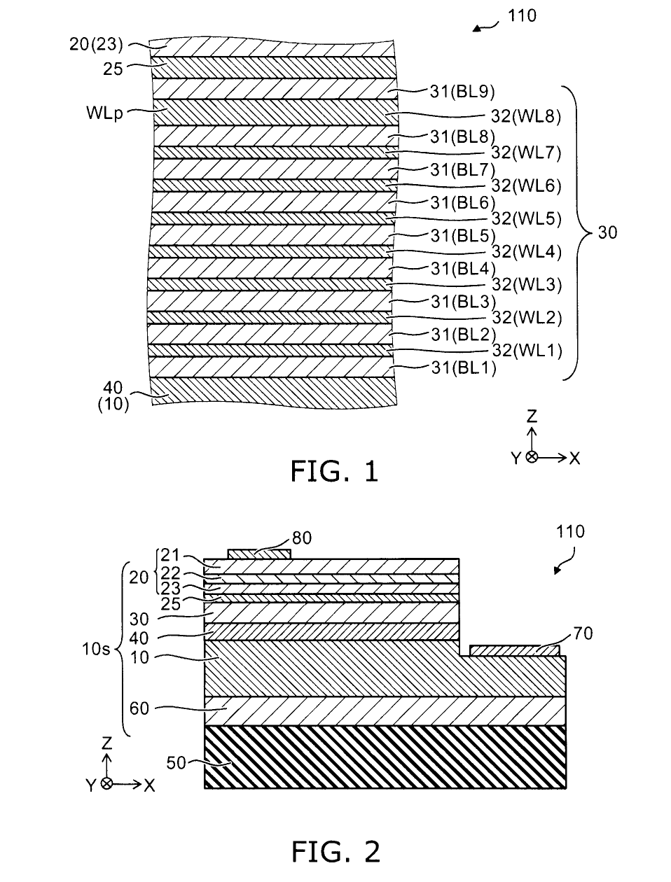

FIG. 1 is a schematic cross-sectional view illustrating a configuration of a semiconductor light emitting device according to a first embodiment.

FIG. 2 is a schematic cross-sectional view illustrating a whole configuration of the semiconductor light emitting device according to the first embodiment.

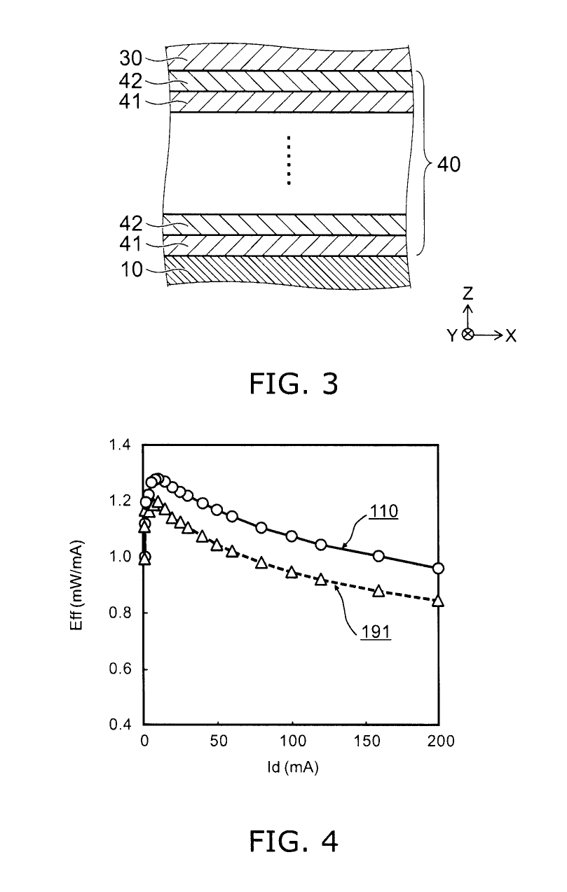

FIG. 3 is a schematic cross-sectional view illustrating a configuration of part of the semiconductor light emitting device according to the first embodiment.

As shown in FIG. 2, a semiconductor light emitting device 110 according to the embodiment includes an n-type semiconductor layer 10, a p-type semiconductor layer 20, and a light emitting part 30. The light emitting part 30 is provided between the n-type semiconductor layer 10 and the p-type semiconductor layer 20.

Here, a direction going from the n-type semiconductor layer 10 toward the p-type semiconductor layer 20 is defined as the Z-axis direction. An axis perpendicular to the Z-axis is defined as the X-axis. A direction perpendicular to the Z-axis and the X-axis is defined as the Y-axis. The Z-axis is parallel with a stacking direction of stacked structure body 10s including the n-type semiconductor layer 10, the light emitting part 30, and the p-type semiconductor layer 20.

In the specification, “stacking” includes, other than overlaying layers in contact with each other, a case where another layer is inserted and overlaid therebetween.

The n-type semiconductor layer 10 and the p-type semiconductor layer 20 include nitride semiconductors.

In this example, the semiconductor light emitting device 110 further includes a substrate 50. For example, a sapphire substrate, (e.g., a c-plane sapphire substrate) is used as the substrate 50. For example, a substrate such as GaN, SiC, ZnO, or Si may be used as the substrate 50.

The stacked structure body 10s may further include a foundation layer 60. The n-type semiconductor layer 10 is disposed between the foundation layer 60 and the light emitting part 30. A buffer layer (not shown) may be further provided between the substrate 50 and the foundation layer 60. The buffer layer is formed on the substrate 50, and on thereon, the foundation layer 60, the n-type semiconductor layer 10, the light emitting part 30, and the p-type semiconductor layer 20 are formed in this order. The substrate 50 may be removed after the stacked structure body 10s has been formed on the substrate 50. When performing the removal, at least a part of the foundation layer 60 may be removed.

An undoped GaN layer, for example, may be used as the foundation layer 60. The thickness of the foundation layer 60 is about 3 micrometers (μm), for example.

An n-type GaN layer containing silicon (Si) doped therein, for example, is used as the n-type semiconductor layer 10. The concentration of doped Si is about 8×10¹⁸ (atoms/cm³), for example. The thickness of the n-type semiconductor layer 10 is about 5 μm, for example. At least a part of the n-type semiconductor layer 10 functions as an n-type cladding layer.

The p-type semiconductor layer 20 includes a first p-type layer 21, a second p-type layer 22, and a third p-type layer 23. The light emitting part 30 is provided between the first p-type layer 21 and the n-type semiconductor layer 10. The second p-type layer 22 is provided between the first p-type layer 21 and the light emitting part 30. The third p-type layer 23 is provided between the second p-type layer 22 and the light emitting part 30. The first p-type layer 21, the second p-type layer 22, and the third p-type layer 23 contain, for example, Mg doped therein as p-type impurities.

A p-type AlGaN layer, for example, is used as the third p-type layer 23. The third p-type layer 23 has a function of, for example, confining electrons in the light emitting part 30. Alₓ₂Ga₁₋ₓ₂N (0<x2<1), for example, is used as the third p-type layer 23. x2 is set not less than 0.1 and not more than 0.2, for example. The Mg concentration in the third p-type layer 23 is set not less than 1×10¹⁹ cm⁻³ and not more than 1×10²⁰ cm⁻³, for example. The thickness of the third p-type layer 23 is about 10 nanometers (nm), for example.

A p-type GaN layer, for example, is used as the second p-type layer 22. The second p-type layer 22 functions as a p-side cladding layer. The Mg concentration in the second p-type layer 22 is set not less than 1×10¹⁹ cm⁻³ and not more than 1×10²⁰ cm⁻³, for example. The thickness of the second p-type layer 22 is about 50 nm, for example.

A p-type GaN layer, for example, is used as the first p-type layer 21. The first p-type layer 21 functions as a p-side contact layer. The first p-type layer 21 contains Mg doped with a concentration higher than the Mg concentration in the second p-type layer 22. The Mg concentration in the first p-type layer 21 is set not less than 1×10²⁰ cm⁻³ and not more than 3×10²¹ cm⁻³, for example. The thickness of the first p-type layer 21 is about 10 nm, for example.

In this example, a cap layer 25 is provided between the third p-type layer 23 and the light emitting part 30. An Alₓ₃Ga₁₋ₓ₃N layer, for example, is used as the cap layer 25. The composition ratio (x3) of Al in the cap layer 25 is not less than 0.003 and not more than 0.03, for example. The Mg concentration in the cap layer 25 is lower than that in the p-type semiconductor layer 20 (e.g., the third p-type layer 23). An undoped AlGaN layer is used as the cap layer 25. The thickness of the cap layer 25 is not less than 3 nm and not more than 5 nm, for example. The cap layer 25 may be regarded as a part of the p-type semiconductor layer 20.

The semiconductor light emitting device 110 may further include a first electrode 70 and a second electrode 80. The first electrode 70 is electrically connected to the n-type semiconductor layer 10. The second electrode 80 is electrically connected to the p-type semiconductor layer 20.

A stacked film such as Ti film/Pt film/Au film, for example, is used as the first electrode 70. A stacked film such as Ni film/Au film, for example, is used as the second electrode 80.

In the example, in the stacked structure body 10s, a part of the n-type semiconductor layer 10 and the p-type semiconductor layer 20 are exposed on the major surface of the stacked structure body 10, the major surface being on a side of the p-type semiconductor layer 20. The first electrode 70 and the second electrode 80 are connected to the n-type semiconductor layer 10 and the p-type semiconductor layer 20 respectively, on the side of the major surface.

Current is supplied to the light emitting part 30 via the n-type semiconductor layer 10 and the p-type semiconductor layer 20 by applying the voltage between the first electrode 70 and the second electrode 80, and thereby light is emitted from the light emitting part 30.

As shown in FIG. 2, the stacked structure body 10s may further include an intermediate layer 40. The intermediate layer 40 is provided between the n-type semiconductor layer 10 and the light emitting part 30.

FIG. 3 illustrates a configuration of the intermediate layer 40.

As shown in FIG. 3, the intermediate layer 40 includes a plurality of first layers 41 and a plurality of second layers 42 which are alternately stacked along the Z-axis.

A Si-doped n-type GaN layer, for example, is used as the first layer 41. The concentration of doped Si in the first layer 41 is about 2×10¹⁸ (atoms/cm³), for example. An undoped InGaN layer, for example, is used as the second layer 42. Specifically, undoped Inₓ₄Ga₁₋ₓ₄N (0<x4<0.1), for example, is used as the second layer 42. The thickness of the first layer 41 is about 3 nm, for example. The thickness of the second layer 42 is about 1 nm, for example. The intermediate layer 40 has a superlattice structure. In this example, the number of the second layers 42 is not less than 30.

As shown in FIG. 1, the light emitting part 30 includes a plurality of well layers 32 and barrier layer 31 provided between the well layers 32. In other words, the well layers 32 and the barrier layers 31 are alternately stacked along the Z-axis.

The well layers 32 include Inₓ₁Ga₁₋ₓ₁N (0<x1<1). The barrier layer 31 includes GaN. In other words, the well layers 32 contain In, whereas the barrier layers 31 do not substantially contain In. The band gap energy of the barrier layer 31 is larger than that of the well layer 32.

As thus described, the light emitting part 30 has a Multi Quantum Well (MQW) structure. In the embodiment, the number of the well layers 32 is not less than 8.

In other words, the light emitting part 30 includes (n+1) barrier layers 31 and n well layers 32 (“n” is an integer not less than 8). The (i+1)-th barrier layer BL(i+1) is disposed between the i-th barrier layer BLi and the p-type semiconductor layer 20 (“i” is an integer not less than one and not more than (n−1)). The (i+1)-th well layer WL(i+1) is disposed between the i-th well layer WLi and the p-type semiconductor layer 20. The first barrier layer BL1 is provided between the n-type semiconductor layer 10 and first well layer WL1. The n-th well layer WLn is provided between the n-th barrier layer BLn and the (n+1)-th barrier layer BL(n+1). The (n+1)-th barrier layer BL(n+1) is provided between the n-th well layer WLn and the p-type semiconductor layer 20.

The peak wavelength of the light (emitted light) emitted from the light emitting part 30 is not less than 400 nm and not more than 650 nm, for example.

In the semiconductor light emitting device 110 according to the embodiment, the p-side well layer WLp nearest to the p-type semiconductor layer 20 (the eighth well layer WL8 in this example) among the well layers 32 is thicker than all the well layers 32 except the p-side well layer WLp among the well layers 32 (the first well layer WL1 to the seventh well layer WL7 in this example). That is, the well layers 32 includes a p-side well layer WLp, which is nearest to the p-type semiconductor layer 20 among the well layers 32, and other well layers, which are all well layers 32 except the p-side well layer WLp among the well layers 32. The other well layers correspond to the first well layer WL1 to the seventh well layer WL7 in this example. Then, the p-side well layer WLp is thicker than the other well layers. Here, the thickness of the well layer 32 is the thickness along the Z-axis.

The In composition ratio in the p-side well layer WLp is lower than that in each of all the well layers 32 except the p-side well layer WLp (the first well layer WL1 to the seventh well layer WL7 in this example). That is, The In composition ratio in the p-side well layer WLp is lower than the In composition ratio in the other well layers. The In composition ratio in the well layer 32 is x1 in Inₓ₁Ga₁₋ₓ₁N.

The thickness of the barrier layer 31 (the thickness along the Z-axis) is not more than twice that of the p-side well layer WLp.

For example, the thickness of each of the first well layer WL1 to the seventh well layer WL7 is about 3 nm. The In composition ratio (x1) in the first well layer WL1 to the seventh well layer WL7 is 0.15. The peak wavelength of light emission in the first well layer WL1 to the seventh well layer WL7 is about 450 nm.

On the other hand, the thickness of the eighth well layer WL8 is about 5 nm. The In composition ratio (x1) in the eighth well layer WL8 is 0.14. The peak wavelength of light emission in the eighth well layer WL8 is about 440 nm.

The thickness of the barrier layer 31 (the first barrier layer BL1 to the ninth barrier layer BL9) is about 5 nm. In other words, the thickness of the barrier layer 31 is substantially equal to that of the p-side well layer WLp. The barrier layer 31 does not contain In substantially.

In this example, the cap layer 25 including an undoped AlGaN layer is provided. As described above, the thickness of the cap layer 25 is not less than 3 nm and not more than 5 nm, for example. The total thickness of the cap layer 25 and the ninth barrier layer BL9 is not less than 8 nm and not more than nm. The total thickness is not more than twice the thickness of the p-side well layer WLp, also when the composition ratio of Al in the cap layer 25 is low and the cap layer 25 is regarded as the GaN layer.

The thickness of the well layer 32 and the thickness of the barrier layer 31 can be obtained by observing the light emitting part 30 with an electron microscope, for example. In addition, the In composition ratio in the well layer 32 can be obtained by analysis based on X-ray diffraction, or quantitative analysis based on TEM-EDX (transmission electron microscope—energy-dispersive X-ray spectrography), for example.

With the above-mentioned configuration, a high light emission efficiency is obtained over a wide current density range. An experiment which is the basis of building the configuration of the semiconductor light emitting device according to the embodiment will be described below.

The manufacturing method described below is an example of a manufacturing method of the semiconductor light emitting device 110. For example, organic cleaning and acid cleaning were performed on the c-plane sapphire substrate 50 as a preprocessing. Subsequently, the substrate 50 was introduced in a reaction chamber of a MOCVD (Metal Organic Chemical Vapor Deposition) device. The temperature of the substrate 50 is raised to 1100° C. by high-frequency heating in a normal pressure mixed gas atmosphere of nitrogen (N₂) gas and hydrogen (H₂) gas. Accordingly, gas-phase etching is performed on the surface of the substrate 50, and thereby the natural oxidation film formed on the surface is removed.

The temperature of the substrate 50 is lowered to 500° C., and ammonia (NH₃) gas, Tri-Methyl Gallium (TMG), and Tri-Methyl Aluminum (TMA), for example, are supplied as the process gas, with mixed gas of N₂ and H₂ being the carrier gas, to form a buffer layer (low temperature buffer layer) on the substrate 50.

Next, supply of TMG and TMA gas was stopped while continuing supply of NH₃ gas, and then the temperature was raised to 1100° C. Supply of TMG was supplied again while maintaining the temperature, and an undoped GaN layer (with a thickness of 3 μm) serving as the foundation layer 60 was formed.

Next, silane (SiH₄) gas was supplied as an n-type dopant with the process gas being maintained, and an n-type GaN layer (with a Si doping concentration of 8×10¹⁸ atoms/cm³ and a thickness of 5 μm) serving as the n-type semiconductor layer 10 was formed.

Next, supply of TMG and SiH₄ gas was stopped while continuing supply of NH₃ gas, and then the temperature of the substrate 50 was lowered to and maintained at 800° C.

The intermediate layer 40 was formed at this temperature. Specifically, NH₃ gas, TMG, and SiH₄ gas were supplied as the process gas, with N₂ gas being the carrier gas, and an n-type GaN layer (with an Si doping concentration of 2×10¹⁸ atoms/cm³ and a thickness of 3 nm) serving as the first layer 41 was formed. Subsequently, after having stopped supply of SiH₄ gas, Tri-Methyl Indium (TMI) was further supplied, and an undoped InGaN layer (with a thickness of 1 nm, and an In composition ratio of 0.07) serving as the second layer 42 was formed.

The intermediate layer 40 having a superlattice structure of the first layer 41 and the second layer 42 was formed by repeating supply of SiH₄ gas and TMI alternately for 30 periods.

Next, the light emitting part 30 was formed. Specifically, the N₂ carrier gas and the NH₃ and TMG process gas were supplied, and a GaN layer (with a thickness of 5 nm) serving as the first barrier layer BL1 as formed. Subsequently, Tri-Methyl Indium (TMI) was further supplied, and an InGaN layer (with a thickness of 3 nm, and an In composition ratio of 0.15) serving as first well layer WL1 was formed.

Furthermore, a GaN layer (with a thickness of 5 nm) serving as the second to eighth barrier layers BL2 to BL8, and an InGaN layer (with a thickness of 3 nm, and an In composition ratio of 0.15) serving as the second well layer WL2 to the seventh well layer WL7 were formed by intermittently supplying TMI.

Further, TMI was supplied, and an InGaN layer (with a thickness of 5 nm, and an In composition ratio of 0.14) serving as the p-side well layer WLp (the eighth well layer WL8) was formed on the eighth barrier layer BL8. Supply of TMI is then stopped, and a GaN layer (with a thickness of 5 nm) serving as the ninth barrier layer BL9 was formed on the eighth well layer WL8. Accordingly, the light emitting part 30 is formed. Further, TMA is supplied, and an AlGaN layer (for example, undoped) serving as the cap layer 25 is formed on the light emitting part 30 (on the ninth barrier layer BL9). Although the thickness of the AlGaN layer immediately after the AlGaN layer is formed is 5 nm, for example, the thickness of the AlGaN layer becomes about 3 nm by subsequent rise of temperature.

Next, supply of TMG was stopped, while continuing supply of NH₃ gas, and the temperature of the substrate 50 was raised to and maintained at 1030° C. in the N₂ gas atmosphere.

At this temperature, NH₃ gas, TMG, and TMA as the process gas and bis-cyclopentadienyl magnesium (Cp₂Mg) as a p-type dopant were supplied, with mixed gas of N₂ and H₂ being the carrier gas, then a p-type AlGaN layer (with a Mg concentration not less than 1×10¹⁹ and not more than 1×10²⁰ cm⁻³, and a thickness of 10 nm) serving as the third p-type layer 23 was formed.

Next, supply of TMA was stopped while continuing supply of TMG and Cp₂Mg, and a p-type GaN layer (with an Mg concentration of about 3×10¹⁹ cm⁻³, and a thickness of about 50 nm) serving as the second p-type layer 22 was formed.

Next, the amount of Cp₂Mg supplied was increased, and a p-type GaN layer (with an Mg concentration of about 1×10²¹ cm⁻³, and a thickness of about 10 nm) serving as the first p-type layer 21 was formed.

Next, supply of TMG and Cp₂Mg was stopped while continuing supply of NH₃ gas, with only the carrier gas kept being supplied, and the substrate 50 was naturally cooled down. Supply of NH₃ gas was continued until the temperature of the substrate 50 reached 300° C.

After having taken out the substrate 50 from the MOCVD apparatus, a part of the stacked structure body 10s is removed by RIE (Reactive Ion Etching) until reaching the n-type semiconductor layer 10. Ti/Pt/Au films are formed on the exposed n-type semiconductor layer 10, and thereby the first electrode 70 is formed.

In addition, Ni/Au films are formed on the first p-type layer 21, and thereby the second electrode 80 is formed. Accordingly, the semiconductor light emitting device 110 according to the embodiment was obtained.

In this experiment, the following semiconductor light emitting devices 191 to 193 (not shown) of first to third reference examples have also been fabricated. The configuration of the semiconductor light emitting devices 191 to 193 is same as that of the semiconductor light emitting device 110 except the light emitting part 30. In the following, the light emitting part 30 of each of the semiconductor light emitting devices 191 to 193 will be described.

In the semiconductor light emitting device 191 of the first example, the number of the well layers 32 is eight. Each of all the well layers 32 (the first well layer WL1 to the eighth well layer WL8) has a thickness of about 3 nm, and an In composition ratio x1 of 0.15. The barrier layers 31 (the first barrier layer BL1 to the ninth barrier layer BL9) are GaN layers, each having a thickness of about 5 nm.

In the semiconductor light emitting device 192 of the second example, the number of the well layers 32 is four. The thickness of each of the first well layer WL1 to the third well layer WL3 is about 3 nm, and the In composition ratio (x1) in the first well layer WL1 to the third well layers WL3 is 0.15. The thickness of the fourth well layer WL4 is about 5 nm, and the In composition ratio (x1) in the fourth well layer WL4 is 0.14. The barrier layers 31 (the first barrier layer BL1 to the fifth barrier layer BL5) are GaN layers each having a thickness of about 5 nm.

In the semiconductor light emitting device 193 of the third example, the number of the well layers 32 is one. The thickness of the well layer 32 is about 5 nm, and the In composition ratio (x1) in the well layer 32 is 0.14. The barrier layers 31 (the first barrier layer BL1 and the second barrier layer BL2) are GaN layers, each having a thickness of about 5 nm.

The semiconductor light emitting devices 191 to 193 have been fabricated by varying the condition of the barrier layer 31 and the well layer 32 in the manufacturing method described with regard to the semiconductor light emitting device 110.

FIG. 4 is a graph illustrating the characteristics of the semiconductor light emitting devices.

FIG. 4 illustrates the characteristics of the semiconductor light emitting device 110 according to the embodiment and the semiconductor light emitting device 191 of the first reference example. The horizontal axis indicates current Id (milliampere: mA). The vertical axis indicates light emission efficiency Eff (milliwatt/milliampere: mW/mA). The intensity of light emitted from the semiconductor light emitting device was measured by an integrating sphere while varying the current supplied to the semiconductor light emitting device. The light emission efficiency Eff was calculated by dividing the obtained intensity of light by the current Id.

As shown in FIG. 4, in the semiconductor light emitting device 191 of the first reference example, when the current Id is large, i.e., the current density is high, the light emission efficiency Eff decreases significantly.

On the contrary, in the semiconductor light emitting device 110 according to the embodiment, decrease of the light emission efficiency Eff is moderate when the current Id increases. In the semiconductor light emitting device 110, a higher light emission efficiency Eff than the semiconductor light emitting device 191 was obtained in a wide current region ranging from small current region to larg current region.

As thus described, in the semiconductor light emitting device 110, a higher light emission efficiency Eff than that in the semiconductor light emitting device 191, which is similar in that the number of the well layers 32 is eight, is obtained in a wide current range.

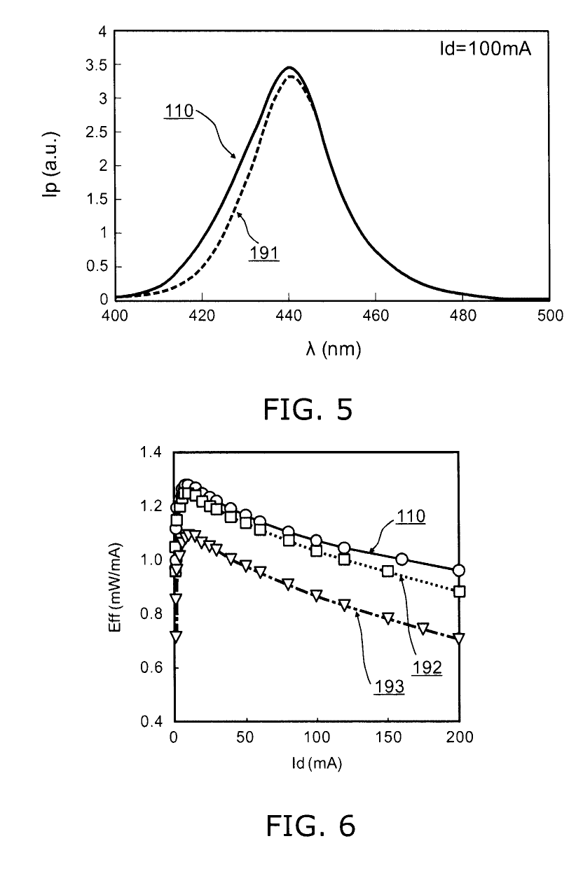

FIG. 5 is a graph illustrating the characteristics of the semiconductor light emitting device.

That is, FIG. 5 shows the dependence of the semiconductor light emitting device 110 and the electroluminescence (EL) peak shape of the semiconductor light emitting device 191 on current. The horizontal axis indicates the wavelength λ (nm), and the vertical axis indicates the EL peak intensity Ip (arbitrary units).

As can be seen from FIG. 5, the peak wavelength is about 440 nm in the semiconductor light emitting device 191 and the semiconductor light emitting device 110.

Comparing the above-mentioned devices, the semiconductor light emitting device 191 has a sharp peak shape and a low peak intensity. On the other hand, in the semiconductor light emitting device 110, a broad light emission is obtained and the wavelength characteristics having a shoulder in wavelength region short than the peak wavelength. Its peak intensity is high.

FIG. 6 is a graph illustrating the characteristics of the semiconductor light emitting device.

That is, FIG. 6 shows the characteristics of the semiconductor light emitting device 110, the semiconductor light emitting device 192, and the semiconductor light emitting device 193. The horizontal axis indicates the current Id, and the vertical axis indicates the light emission efficiency Eff.

As can be seen from FIG. 6, the light emission efficiency Eff is significantly low in the semiconductor light emitting device 193 of the third reference example in which the number of the well layer 32 is one. In the semiconductor light emitting device 192 of the second reference example in which the number of the well layers 32 is four, the light emission efficiency Eff is still insufficient although it has improved in comparison with the semiconductor light emitting device 193.

As thus described, if the number of the well layers 32 disposed between the p-side well layer WLp and the n-type semiconductor layer 10 is small (0 or 3 in this example), the light emission efficiency Eff is low in comparison with the semiconductor light emitting device 110 (the number of well layers 32 disposed between the p-side well layer WLp and the n-type semiconductor layer 10 is seven).

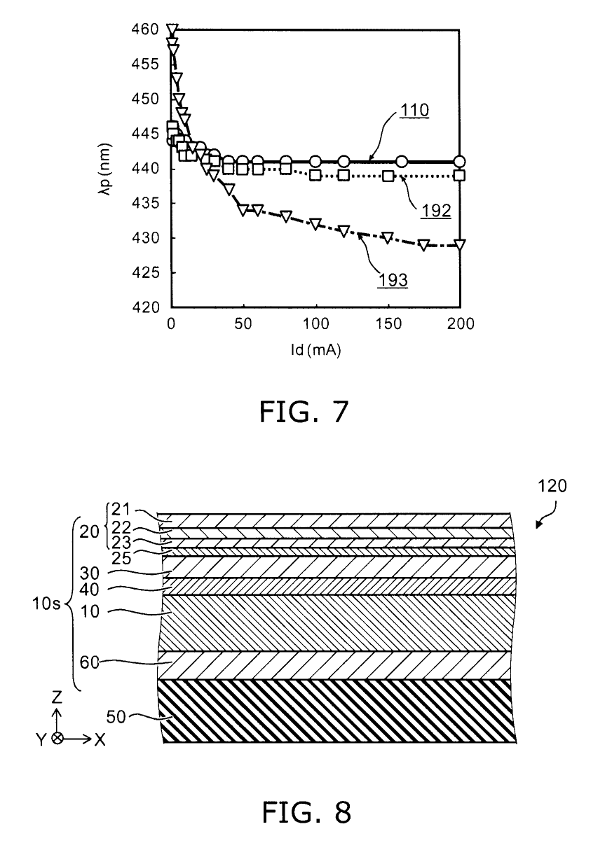

FIG. 7 is a graph illustrating the characteristics of the semiconductor light emitting device.

That is, FIG. 7 shows the characteristics of the semiconductor light emitting device 110, the semiconductor light emitting device 192, and the semiconductor light emitting device 193. The horizontal axis indicates the current Id, and the vertical axis indicates the peak wavelength λp of the light emitted from the light emitting part 30 (nm).

As shown in FIG. 7, the peak wavelength λp becomes short when the current Id increases in any of the semiconductor light emitting device 110, the semiconductor light emitting device 192, and the semiconductor light emitting device 193. In other words, the light emission wavelength becomes short.

The semiconductor light emitting device 193 has a very large amount of shift of the light emission wavelength. In comparison, the semiconductor light emitting device 110 has a small amount of shift. The amount of shift in the semiconductor light emitting device 192 falls between the both. As thus described, the fewer the well layers 32 provided between the p-side well layer WLp and the n-type semiconductor layer 10, the larger the amount of shift of the light emission wavelength.

In the well layer 32 (InGaN layer) formed on the c-plane substrate 50, compression strain occurs due to the difference of lattice constants between InN and GaN. Piezoelectric polarization occurs in association therewith, and thereby a piezoelectric field is generated. Accordingly, it is considered that the substantial band gap energy of the well layer 32 becomes smaller than that of the well layer 32 when no compression strain is applied.

A large amount of shift of the light emission wavelength when the current Id is increased corresponds to a large compression strain which the well layer 32 receives. In other words, in the above example, it is considered that the compression strain which the well layer 32 receives is large in the semiconductor light emitting devices 192 and 193.

A large compression strain in the well layer 32 causes holes and electrons to be spaced apart and results in a decrease of the efficiency of light emission recombination. As thus described, the degree of compression strain in the well layer 32 influences the degree of light emission recombination. It is considered that this phenomena cause the decrease of the light emission efficiency Eff illustrated in FIG. 6.

On the contrary, as illustrated in FIGS. 4 and 6, the semiconductor light emitting device 110 according to the embodiment can suppress the decrease of the light emission efficiency Eff in the current Id having a high current density. It is considered that suppressing the adverse effect of the piezoelectric field of the well layer 32 is contributing thereto.

Against the decrease of the light emission efficiency Eff with increasing the current density in a semiconductor light emitting device, it is conceivable to increase the volume of the light emitting part 30 in order to avoid a current concentration. For example, the well layer 32 may be thickened to increase the volume of the light emitting part 30. With this method, however, influence of the piezoelectric field caused by the compression strain on the well layer 32 is large, and thereby the light emission recombination probability becomes low, resulting in decrease of the light emission efficiency.

Additionally, in order to avoid this, a configuration is conceivable in which the compression strain is weakened by stacking thin films of different In composition ratios in each of the well layer 32 to avoid high current density. However, when layers with different In composition ratios adjacently are provided in each of the well layers 32, it becomes difficult to control the In composition ratio at the interface therebetween. Thereby, a precipitation part having a locally high In mixed crystal ratio may be easily generated. This precipitation part has a poor thermal stability, and its crystal quality degrades in the high temperature process (e.g., forming of the p-type semiconductor layer 20) after the forming of the well layer 32. Therefore, the light emission efficiency Eff may easily decrease.

In addition, there is also a configuration that attempts to reduce the adverse effect of the piezoelectric field in the well layer 32 by using an InGaN layer (e.g., In_{0.01}Ga_{0.99}N layer) as the barrier layer 31. In this case, the thickness of the barrier layer 31 must be increased (e.g., 15 nm) because crystal quality may easily degrade if an InGaN layer is used for the barrier layer 31.

If, for example, in a case of using a thick (e.g., 15 nm) InGaN layer as the barrier layer 31, the thickness of the p-side well layer WLp is made thicker than each of all the well layers 32 except the p-side well layer WLp, and the In composition ratio in the p-side well layer WLp is made lower than that in all the well layers 32 except the p-side well layer WLp, the light emission efficiency Eff may improve in the high current density region in comparison with the case where the thickness and the In composition ratio in all the well layers 32 are made equal. But the light emission efficiency Eff decreases in the low current density region. This comes from that the In precipitation part generated at the interface between the InGaN layer as the barrier layer 31 and the well layer 32 becomes partially defect and this causes a quality degradation of the well layer 32 of the thick film. In other words, it is difficult to improve the light emission efficiency when a thick (e.g., 15 nm) InGaN layer is used as the barrier layer 31 in a large region from a low current density to a high current density.

On the contrary, in the semiconductor light emitting device 110 according to the embodiment, the light emission efficiency can be improved in a wide region from a low current density to a high current density by making the thickness of the p-side well layer WLp thicker than each of all the well layers 32 except the p-side well layer WLp, and making the In composition ratio in the p-side well layer WLp lower than the In composition ratio in all the well layers 32 except the p-side well layer WLp, while using a thin (not less than twice the thickness of the p-side well layer WLp) GaN layer as the barrier layer 31.

In the semiconductor light emitting device 110 according to the embodiment, the compression strain on the p-side well layer WLp where the compression strain becomes particularly large is appropriately relaxed by making the number of the well layer 32 not less than eight. Thereby, the adverse influence of the piezoelectric field in the p-side well layer WLp is suppressed.

Accordingly, it becomes possible to improve the light emission efficiency in a high current density, while suppressing decrease of light emission recombination probability.

In addition, it becomes possible to use a thin GaN layer as the barrier layer 31 because the influence of the piezoelectric field is small. Thereby, a high crystal quality can be maintained and the light emission efficiency Eff in a low current density can be further improved.

In the embodiment, it is preferred that the thickness of the barrier layers 31 be not less than 3 nm and not more than 8 nm. If the thickness of the barrier layers 31 is less than 3 nm, for example, the effect of confining electrons in the well layer 32 is reduced, and the light emission efficiency Eff decreases. If the thickness of the barrier layers 31 exceeds 8 nm, for example, the operation voltage rises. It is further preferred that the thickness of the barrier layers 31 be not more than 5 nm. Accordingly, a high light emission efficiency Eff and a sufficiently low operation voltage are obtained.

In the embodiment, it is preferred that the thickness of the p-side well layer WLp be not less than 4 nm, and the thickness of each of all the well layers 32 except the p-side well layer WLp be less than 4 nm. If the thickness of each of the well layers 32 except the p-side well layer WLp exceeds 4 nm for example, the crystal quality may degrade. In addition, it is preferred for example that the thickness of the p-side well layer WLp be not less than 1.1 times and not more than twice the thickness of each of all the well layers 32 except the p-side well layer WLp.

It is preferred that the In composition ratio in the p-side well layer WLp be less than 0.145 and the In composition ratio in all the well layers 32 except the p-side well layer WLp be not less than 0.145. Accordingly, blue light, which has particularly low light emission efficiency, can be obtained with a high light emission efficiency Eff.

It is preferred that the In composition ratio in the p-side well layer WLp be, for example, not less than 0.8 times and not more than 0.95 times the In composition ratio in each of all the well layers 32 except the p-side well layer WLp.

Although there may be a configuration in which the thickness of the well layer 32 of the light emitting part 30 is varied along the Z-axis, it is difficult in this case to control the thickness, resulting in complicated manufacturing. On the contrary, the semiconductor light emitting device 110 according to an embodiment improves productivity because the thickness of each of the well layers 32 except the p-side well layer WLp may be constant, for example.

### Second Embodiment

The embodiment is related to wafers used for semiconductor light emitting devices such as LEDs and LDs.

FIG. 8 is a schematic cross-sectional view illustrating a configuration of a wafer according to the second embodiment.

As shown in FIG. 8, a wafer 120 according to the embodiment includes the n-type semiconductor layer 10 including a nitride semiconductor, the p-type semiconductor layer 20 including an nitride semiconductor, and the light emitting part 30 provided between the n-type semiconductor layer 10 and the p-type semiconductor layer 20. The wafer 120 may further include the substrate 50. In addition, the wafer 120 may further include the foundation layer 60.

The light emitting part 30 includes the well layers 32 including Inₓ₁Ga₁₋ₓ₁N (0<x1<1) and the barrier layer 31 which is provided between the well layers 32 and including GaN. The p-side well layer WLp nearest to the p-type semiconductor layer 20 among the well layers 32 is thicker than the other well layers (each of all the well layers 32 except the p-side well layer WLp among the well layers 32). The In composition ratio in the p-side well layer WLp is lower than that in the other well layers (all the well layers 32 except the p-side well layer WLp). The thickness of the barrier layers 31 is not more than twice the thickness of the p-side well layer WLp.

Accordingly, a wafer can be provided for the semiconductor light emitting device providing a high light emission efficiency can be obtained in a wide current density range.

The configuration described with regard to the first embodiment can be applied as appropriate for various elements included in the wafer 120 according to the embodiment, and a similar effect can be obtained thereby.

In the above description according to the first and the second embodiments, the thickness and the In composition ratio in the well layer 32 (the thickness and the In composition ratio in the p-side well layer WLp, and the thickness and the In composition ratio in the well layers 32 except the p-side well layer WLp) are an example. In the embodiment, the thickness and the In composition ratio in the well layer 32 may be varied.

In the above, although a case of using MOCVD as the method of forming the semiconductor layer has been described, other formation methods may be used. For example, Halide Vapor Phase Epitaxy (HVPE) or Molecular Beam Epitaxy (MBE) may be used.

Although a case of using TMG, TMA, TMI, and NH3 as the process gas has been described, other process gases may be used. For example, it is possible to use Tri Ethyl Gallium (TEG).

According to the embodiments, semiconductor light emitting devices and wafers can be provided by which a high light emission efficiency can be obtained in a wide current density range.

In the specification, “nitride semiconductor” includes all compositions of semiconductors of the chemical formula BₓIn_{y}Al_{z}Ga_{1-x-y-z}N (0≦x≦1, 0≦y≦1, 0≦z≦1, and x+y+z≦1) for which each of the compositional proportions x, y, and z are changed within the ranges. “Nitride semiconductor” further includes group V elements other than N (nitrogen) in the chemical formula recited above, various elements added to control various properties such as the conductivity type, etc., and various elements included unintentionally.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the invention is not limited to these specific examples. For example, one skilled in the art may similarly practice the invention by appropriately selecting specific configurations of components such as substrates, semiconductor layers, light emitting parts, foundation layers, buffer layers, and electrodes included in semiconductor light emitting devices and wafers etc., from known art. Such practice is included in the scope of the invention to the extent that similar effects thereto are obtained.

Further, any two or more components of the specific examples may be combined within the extent of technical feasibility and are included in the scope of the embodiments to the extent that the spirit of the embodiments is included.

Moreover, all semiconductor light emitting devices and light emitting apparatuses practicable by an appropriate design modification by one skilled in the art based on the semiconductor light emitting devices and the wafers described above as embodiments of the invention also are within the scope of the invention to the extent that the purport of the embodiments of the invention is included.

Furthermore, various modifications and alterations within the spirit of the invention will be readily apparent to those skilled in the art.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor light emitting device comprising:
an n-type semiconductor layer including a nitride semiconductor;
a p-type semiconductor layer including a nitride semiconductor; and
a light emitting part provided between the n-type semiconductor layer and the p-type semiconductor layer, and including:
a plurality of well layers including Inₓ₁Ga₁₋ₓ₁N (0<x1<1); and
a barrier layer provided between the well layers and including GaN,
the well layers including a p-side well layer being nearest to the p-type semiconductor layer among the well layers, and other well layers being all well layers except the p-side well layer among the well layers,
the p-side well layer being thicker than the other well layers,
an In composition ratio in the p-side well layer being lower than an In composition ratio in the other well layers, and
a thickness of the barrier layer being not more than twice a thickness of the p-side well layer.

2. The device according to claim 1, wherein a number of the well layers is not less than eight.

3. The device according to claim 1, wherein the thickness of the barrier layer is not less than 3 nanometers and not more than 8 nanometers.

4. The device according to claim 1, wherein the thickness of the p-side well layer is not less than 4 nanometers, and the thickness of each of the other well layers is less than 4 nanometers.

5. The device according to claim 1, wherein the thickness of the p-side well layer is not less than 1.1 times and not more than twice the thickness of each of the other well layers.

6. The device according to claim 1, wherein the In composition ratio in the p-side well layer is less than 0.145, and the In composition ratio in each of the other well layers is not less than 0.145.

7. The device according to claim 1, wherein the In composition ratio in the p-side well layer is not less than 0.8 times and not more than 0.95 times the In composition ratio in each of the other well layers.

8. The device according to claim 1, wherein a peak wavelength of light emitted from the light emitting part is not less than 400 nanometers and not more than 650 nm.

9. The device according to claim 1, further comprising
a cap layer provided between the light emitting part and the p-type semiconductor layer and including Alₓ₃Ga₁₋ₓ₃N (0.003≦x3≦0.03).

10. The device according to claim 9, wherein a thickness of the cap layer is not less than 3 nanometers and not more than 5 nanometers.

11. A wafer comprising:
an n-type semiconductor layer including a nitride semiconductor;
a p-type semiconductor layer including a nitride semiconductor; and
a light emitting part provided between the n-type semiconductor layer and the p-type semiconductor layer, and including:
a plurality of well layers including Inₓ₁Ga₁₋ₓ₁N (0<x1<1); and
a barrier layer provided between the well layers and including GaN,
the well layers including a p-side well layer being nearest to the p-type semiconductor layer among the well layers, and other well layers being all well layers except the p-side well layer among the well layers,
the p-side well layer being thicker than the other well layers,
an In composition ratio in the p-side well layer being lower than an In composition ratio in the other well layers, and
a thickness of the barrier layer being not more than twice a thickness of the p-side well layer.

12. The wafer according to claim 11, wherein a number of the well layers is not less than eight.

13. The wafer according to claim 11, wherein the thickness of the barrier layer is not less than 3 nanometers and not more than 8 nanometers.

14. The wafer according to claim 11, wherein the thickness of the p-side well layer is not less than 4 nanometers, and the thickness of each of the other well layers is less than 4 nanometers.

15. The wafer according to claim 11, wherein the thickness of the p-side well layer is not less than 1.1 times and not more than twice the thickness of each of the other well layers.

16. The wafer according to claim 11, wherein the In composition ratio in the p-side well layer is less than 0.145, and the In composition ratio in each of the other well layers is not less than 0.145.

17. The wafer according to claim 11, wherein the In composition ratio in the p-side well layer is not less than 0.8 times and not more than 0.95 times the In composition ratio in each of the other well layers.

18. The wafer according to claim 11, wherein a peak wavelength of light emitted from the light emitting part is not less than 400 nanometers and not more than 650 nm.

19. The wafer according to claim 11, further comprising
a cap layer provided between the light emitting part and the p-type semiconductor layer and including Alₓ₃Ga₁₋ₓ₃N (0.003≦x3≦0.03).

20. The wafer according to claim 19, wherein a thickness of the cap layer is not less than 3 nanometers and not more than 5 nanometers.
